(19) United States
(12) Patent Application Publication
(10) Pub. No.: US 2007/0018676 A1
(43) Pub. Date: Jan. 25, 2007

(54) Apparatus for testing semiconductor circuits

(75) Inventors: Klaus Rittberger, Steinheim (DE); Heinrich Wieczorek, Obereisesheim (DE)

Correspondence Address: MCGRATH, GEISSLER, OLDS & RICHARDSON, PLLC, P.O. BOX 1364, FAIRFAX, VA, 22038-1364, US

(73) Assignee: ATMEL Germany GmbH

(21) Appl. No.: 11/491,171

(22) Filed: Jul. 24, 2006

(30) Foreign Application Priority Data
Jul. 23, 2005 (DE) DE 102005 034 475

(51) Int. Cl. G01R 31/26

(52) U.S. Cl. 324/765

(57) ABSTRACT

An apparatus is disclosed for testing integrated semiconductor circuits on wafers, having a measurement card with electronic circuitry for functional verification of the integrated semiconductor circuits on the wafers, and having, connected to the measurement card, a test head with contact needles, which establishes an electrical contact between the measurement card and the integrated semiconductor circuits, wherein there is provided on the apparatus at least one nozzle assembly with at least one nozzle for introducing a gas essentially perpendicular to the surface of the wafer, and the nozzle assembly is joined to the measurement card in an interlocking manner.

This nonprovisional application claims priority under 35 U.S.C. § 119(a) on German Patent Application No. DE 102005034475, which was filed in Germany on Jul. 23, 2005, and which is herein incorporated by reference.

### BACKGROUND OF THE INVENTION

1. Field of the Invention

The present invention relates to an apparatus for testing integrated semiconductor circuits on wafers.

2. Description of the Background Art

Once integrated semiconductor circuits have been fabricated, they undergo functional verification in a test step while they are still integrated in the wafer, which is to say before singulation. The ratio of usable electronic components to the total number of all such components present on a wafer is called “die yield” and is an important performance figure for evaluating the fabrication process and the cost effectiveness of a production line.

An apparatus for testing the wafers typically includes a movable support device, known as a chuck, upon which the wafer can be supported, suctioned by means of a vacuum pump, secured, and moved in the x, y and z directions. In addition, the apparatus contains a measurement card with electronic circuits arranged thereupon, by which the functionality of the integrated semiconductor circuits on the wafer can be checked. Arranged on the underside of the measurement card and connected in an electrically conductive manner thereto by a retaining mechanism is a test head with hair-thin, spring-loaded contact needles which establish the electrical contact between the measurement card and the integrated semiconductor circuits on the wafer. In this context, the measurement card and test head are provided with an aperture into which the contact needles project. The number and arrangement of the contact needles are matched to the particular semiconductor circuits to be tested, and to the contact areas defined thereby. Once the wafer has been positioned, by the movable support device, beneath the contact needles of the test head at the point where the contact areas are located, the support device is moved upward (z position) and the contact areas of the semiconductor circuits are pressed against the tips of the contact needles with a specific contact pressure. During contact, the electronic circuits on the measurement card transmit test signals and evaluate the response signals coming back from the individual integrated semiconductor circuits on the wafer. In addition, voltage and current in the semiconductor circuits are tested as part of the functional verification. After the function of one integrated semiconductor circuit has been tested, the support device with the wafer is advanced to the next component, which in turn is contacted.

The contact areas of an electronic component on a wafer typically include metallic material, for example aluminum, which forms an oxide layer on its surface in air. When the contact needles are pressed against the contact area, this metal oxide layer, which has a thickness of several μm, must be overcome. This process mechanically stresses the contact needle tips in particular, subjecting them to wear that limits their lifetime. It has been shown in practice that the tips of the contact needles oxidize or show deformation after a few test cycles, and deposits on the contact needle tips, in particular, increase the contact resistance.

In the methods that are customary at present, the contact needles must be regularly cleaned or replaced. During this time, the entire testing apparatus is out of operation. This means that the measurement card with the test head and the used contact needles must be removed, and a new test head must be installed.

In addition, a variety of methods for cleaning the tips of the contact needles are known in current practice for increasing the reliability of measurement, such as having the contact needles make intermediate contact with adhesive films or the use of cleaning wafers. However, the disadvantage of these methods is that overall test time of the wafers is increased, resulting in high costs.

In order increase the service life of the contact needles, a variety of materials have also been used to manufacture them. Normally, the needles are made of tungsten steel or a copper/beryllium alloy. However, it is also known from DE 101 50 291 A1, which corresponds to U.S. Publication No. 20040239921, to provide the tips of the contact needles, or their entire surface, with a hard material such as titanium nitride.

The previous methods each have the disadvantage of being either time intensive or very costly on account of the use of expensive materials and production methods.

### SUMMARY OF THE INVENTION

It is therefore an object of the present invention to increase the service life of the contact needles and improve the measurement reliability of the test apparatus while avoiding the aforementioned disadvantages.

In accordance therewith, the an apparatus for testing integrated semiconductor circuits on wafers is provided that includes a measurement card for functional verification of the integrated semiconductor circuits on the wafers, and, connected to the measurement card, a test head with contact needles which establishes an electrical contact between the measurement card and the integrated semiconductor circuits. There is provided on the apparatus at least one nozzle assembly with at least one nozzle for introducing a gas into the region of the test head, wherein the nozzle assembly is joined to the measurement card in an interlocking manner.

Since the arrangement and number of contact needles, as well as the associated circuit arrangement on the measurement card and the shape of the measurement card, all depend on the components to be tested, the geometry of the test apparatuses also changes with the semiconductor circuits. The nozzle assembly is also matched to the relevant geometry of the apparatus, and designed such that an interlocking connection is produced between the measurement card and nozzle assembly.

In a further embodiment of the invention, provision is made to introduce an inert gas, preferably nitrogen. A number of advantages result simultaneously in the functional verification owing to the displacement of air in the wafer test region. Firstly, the contact resistance at the contact areas of the integrated semiconductor circuits is lower, since the oxidation of the contact areas in the region of contact is reduced significantly. In addition, as a result of the inflow of the gas, only very few ions and polar molecules (H₂O) are present in the region of the contact areas, which has a beneficial effect on the insulating properties of the surface between the contact areas. In principle, because of the existing residual conductivity of the surface, the result is a parallel connection of resistances during the functional verification, including the resistance at the surface between the contact areas being measured and the resistance of the circuit components in the substrate of the wafer being measured. In actuality, however, only the electrical properties of the circuit components in the substrate of the wafer should be analyzed. Thus, the higher the resistance is between the contact areas being measured, the more likely it is that the effects of the conductivity of the surface can be ignored, and thus the electrical properties of the circuit components to be measured can be evaluated even with high-resistance measurements.

According to an embodiment of the invention, the flow of gas around the contact needles of the test head during the functional verification can be laminar. In this way, turbulence between the inert gas and the normal atmosphere, which can distort the test results, is avoided.

According to a further embodiment of the invention, it is advantageous to provide an interchangeable adapter between the nozzle assembly and measurement card in order to accommodate the different geometric designs of the measurement cards and their apertures, as well as distances between the measurement card and wafer. The interchangeable adapter can be pushed onto the nozzle assembly, which is preferably cylindrical in shape. In this way, the same nozzle assembly can always be used on all measurement cards. The interchangeable adapter allows economical and rapid matching of the apparatus to different designs of the measurement cards.

Additionally, according to a further embodiment of the invention, the nozzle assembly can pass through the measurement card in the region of an aperture that is provided for the test head with the contact needles, and is essentially centered within the aperture. As a result, the nozzle is located above the tips of the contact needles. In this way, the contact needle tips are additionally cooled by the gas flowing by, and deposits are avoided.

Another embodiment provides for the nozzle assembly to seal the aperture in the measurement card. This has the advantage that the incoming inert gas cannot escape upward into the volume of the apparatus located above the measurement card, so a high gas concentration prevails in the region of the contact areas of the semiconductor circuits under test and the contact needles.

A further embodiment of the invention provides for the nozzle assembly to be designed in multiple parts. As a result, the nozzle assembly can be easily adapted to different measurement arrangements and geometric conditions, and the component parts of the nozzle assembly can be assembled in accordance with the dimensions at hand.

In the case of differing temperature stresses, readjustment of the apparatus, in particular of the measurement card and test head with contact needles, is usually required. Accordingly, provision is made in an embodiment for the nozzle assembly to be held on the apparatus in a height-adjustable manner. In this way, a height adjustment between the nozzle assembly and the measurement card can take place.

According to a further embodiment of the invention in this regard, an external thread is provided on the nozzle assembly. The advantage of this embodiment is that fine adjustment of the nozzle assembly on the apparatus is possible in an easy and fast way, which is necessary in the event of changing temperatures, on account of the changes in length of the individual components on the apparatus, in order to be able to maintain the dimensional tolerances during the functional verification.

A further embodiment of the invention provides a controller for controlling the flow rate of the gas through the nozzle. The advantage of this design, which preferably includes an electronic control circuit, regulates the flow rate of the gas as a function of predefined parameters such as, for example, temperature or humidity, and as a result, optimal conditions can be provided in the region of the contact areas and contact needles.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a section through a test head with contact needles during probing of a wafer;

FIG. 2 shows a top view of a test head with contact needles during probing of a wafer;

FIG. 3 shows a perspective view of a test head with contact needles during probing of a wafer;

FIG. 4 shows a section through a nozzle assembly and its attachment to an apparatus for testing integrated semiconductor circuits on wafers; and

FIG. 5 shows a longitudinal section through the apparatus for testing integrated semiconductor circuits on wafers.

### DETAILED DESCRIPTION

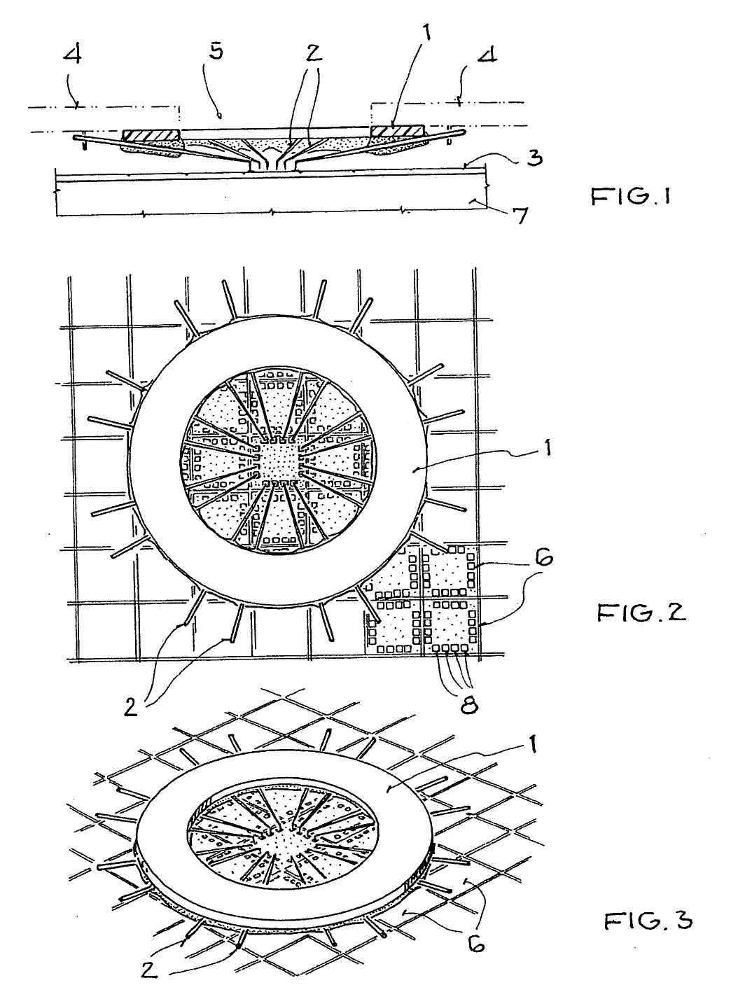

FIG. 1 shows a section through test head 1 with contact needles 2 during probing of a wafer 3, which is supported on a support device 7. The test head 1 is affixed to the underside of a measurement card 4, which is only shown schematically, and is connected thereto in an electrically conductive manner. The measurement card normally has a circular aperture 5, which affords a view from above of the region of the contact needles 2.

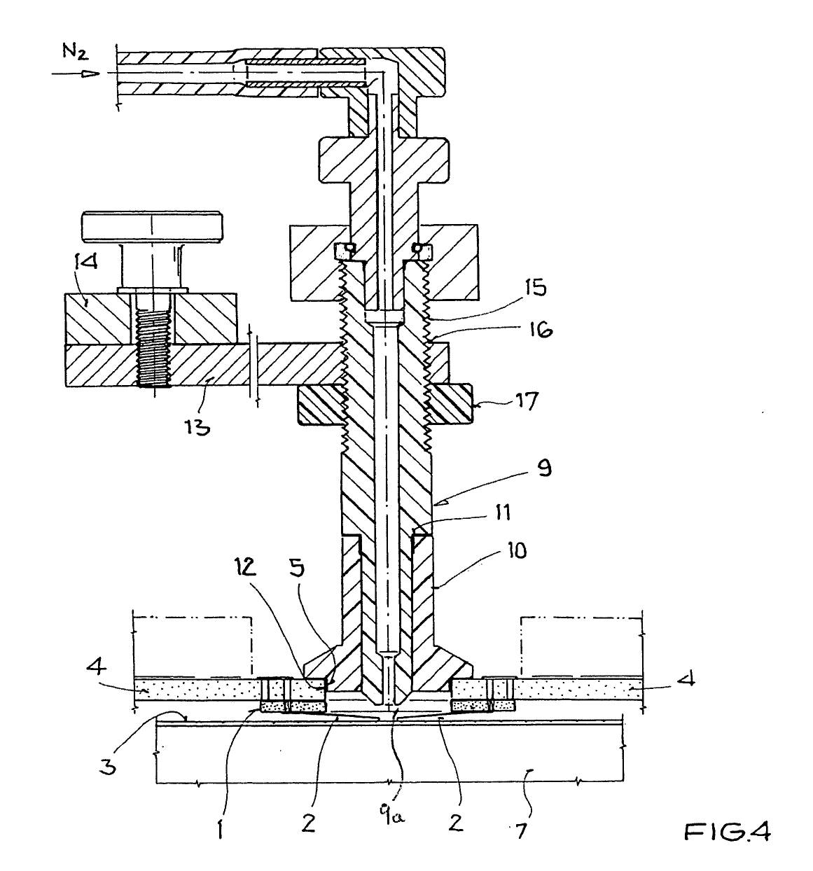

The top view of the test head 1 in FIG. 2 and its perspective view in FIG. 3 schematically show several components of integrated semiconductor circuits 6 on the wafer 3 and the arrangement of contact areas 8, which are probed by the contact needles 2. The arrangement and number of contact needles 2, as well as the associated circuit arrangement on the measurement card and the shape of the measurement card 4 itself, depend on the electronic components to be tested in each case.

FIG. 4 shows a section through a nozzle assembly 9 and its attachment to an apparatus for testing integrated semiconductor circuits on wafers 3. According to an embodiment of the invention, the nozzle assembly 9 passes through the measurement card 4, nitrogen being introduced through a nozzle 9a into the region of the test head 1 above the contact needles 2. The wall thickness of the nozzle assembly 9, which has a circular cross-section, decreases abruptly in a region above the outlet so that a shoulder 11 is produced. An interchangeable adapter 10 is pushed over the portion of the nozzle assembly 9 with reduced wall thickness, resting against the shoulder 11 and thus being fixed in place. The interchangeable adapter 10 steadily increases in size in the lower region facing the measurement card 4, and covers the circular aperture 5 of the measurement card 4. A shoulder 12 is likewise provided on the underside of the interchangeable adapter 10, with the diameter of the remaining cross-section of the interchangeable adapter 10 corresponding substantially to the diameter of the circular aperture 5 of the measurement card 4, thus producing an interlocking fit between the nozzle assembly 9 and the measurement card 4.

The nozzle assembly 9 is screwed to a crossbar 14 of the test apparatus 18 through an extension arm 13. While the extension arm 13 is rigidly attached to the test apparatus 18, the nozzle assembly 9 is held on the extension arm 13 in a height-adjustable manner. To this end, the nozzle assembly 9 is equipped with an external thread 15 and the extension arm 13 is equipped with a threaded hole 16. The position is locked by a lock nut 17. As a result of this design, the nozzle assembly 9 can be adapted to different spacings between the test apparatus and the wafer 3 resulting from different measurement cards 4 and circuit arrangements, and can also be readjusted in the event of different temperature stresses during the test process and the associated changes in length.

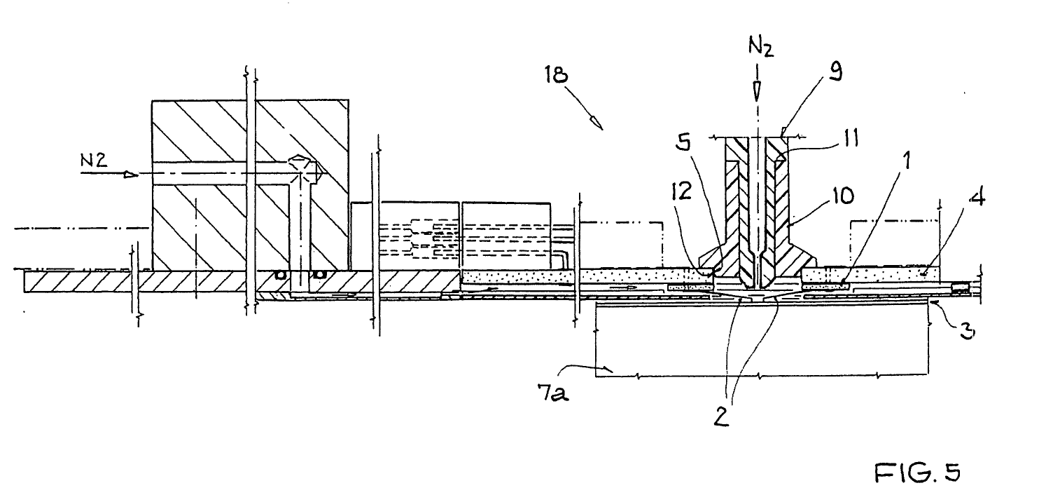

FIG. 5 shows a longitudinal section through the test apparatus 18. According to an embodiment, the wafer 3 is heated during the functional verification by a heatable support device, known as a hot chuck 7a, so that the adhesion of water to the surface of the wafer 3 is further reduced. The subsequent or simultaneous flushing of the area around the test head 1 with an inert gas contributes to high measurement reliability. While the residual conductivity of the surface between the relevant contact areas is reduced to a minimum, the inflowing gas also gives rise to a cooling effect for the other components of the test apparatus 18, in particular the contact needles.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. An apparatus for testing integrated semiconductor circuits on a wafer, comprising:
a measurement card having electronic circuitry for functional verification of the integrated semiconductor circuits on the wafers;
a test head being connected to the measurement card, the test head having contact needles, which establishes an electrical contact between the measurement card and the integrated semiconductor circuits; and
at least one nozzle assembly being provided on the apparatus, the nozzle assembly including at least one nozzle for introducing a gas substantially perpendicular to a surface of the wafer, the nozzle assembly being joined to the measurement card in an interlocking manner.

2. The apparatus according to claim 1, characterized in that the nozzle assembly passes through the measurement card in the region of an aperture that is provided for the test head with the contact needles, and is substantially centered within the aperture.

3. The apparatus according to claim 2, wherein the nozzle assembly forms a substantially impenetrable seal for the aperture of the measurement card.

4. The apparatus according to claim 1, wherein the nozzle assembly is formed of a plurality of interchangeable portions.

5. The apparatus according to claim 1, wherein at least one interchangeable adapter is provided for the interlocking connection with the measurement card at the nozzle assembly.

6. The apparatus according to claim 1, wherein the nozzle assembly is provided on the apparatus in a height-adjustable manner.

7. The apparatus according to claim 1, wherein an external thread is provided on the nozzle assembly.

8. The apparatus according to claim 1, wherein the nozzle assembly directs an inert gas toward the integrated semiconductor circuits.

9. The apparatus according to claim 1, wherein the inert gas is nitrogen.
